(19) United States
(12) Patent Application Publication
(10) Pub. No.: US 2009/0000766 A1
(43) Pub. Date: Jan. 1, 2009

(54) Cooling Structure for Heat Generating Device

(75) Inventor: Michel Cadio, Carmel, IN (US)

Correspondence Address: FLETCHER YODER P.C., 7915 FM 1960 RD. WEST, SUITE 330, HOUSTON, TX, 77070, US

(73) Assignee: TTE TECHNOLOGY, INC., Indianapolis, IN (US)

(21) Appl. No.: 12/280,889

(22) PCT Filed: Mar. 3, 2006
(86) PCT No.: PCT/US06/08017

§ 371 Date: Aug. 27, 2008

(51) Int. Cl. F24F 7/00; H05K 7/20

(52) U.S. Cl. 165/59; 454/309; 361/690

(57) ABSTRACT

The disclosed embodiments relate to a system and method that is adapted to cool a heat generating device. An electronic device in accordance with an exemplary embodiment of the present invention comprises an enclosure that contains a source of heat, and a cooling structure adjacent to the enclosure, the cooling structure being adapted to draw an internal intake comprising heat generated by the source of heat and to draw an external intake from outside the enclosure, the cooling structure being further adapted to combine the internal intake with the external intake to form an exhaust.

### CROSS-REFERENCE TO RELATED APPLICATIONS

This application is a National Phase 371 Application of PCT Application No. PCT/US06/08017, filed Mar. 3, 2006, entitled “COOLING STRUCTURE FOR HEAT GENERATING DEVICE”.

### FIELD OF THE INVENTION

The present invention relates generally to the removal from heat from electronic devices. More specifically, the present invention relates to an improved cooling structure that removes heat from an enclosure such as a projection television system.

### BACKGROUND OF THE INVENTION

This section is intended to introduce the reader to various aspects of art, which may be related to various aspects of the present invention that are described and/or claimed below. This discussion is believed to be helpful in providing the reader with background information to facilitate a better understanding of the various aspects of the present invention. Accordingly, it should be understood that these statements are to be read in this light, and not as admissions of prior art.

Many components that make up electronic devices or systems such as projection televisions generate heat during normal operation. It is typically desirable to disperse generated heat to prevent overheating and facilitate efficient operation of the system. An example of an electronic component that generates a large amount of heat in an associated system is a high power lamp in a digital light projection (DLP) or liquid crystal display (LCD) television system. The high power lamp is used to generate a video display for viewing by a user.

Many systems comprise enclosures into which electrical and/or electronic components are placed in very close proximity to reduce overall system size. In such systems, space within the enclosure is at a premium. Dispersing heat from a high-power lamp disposed in a relatively confined television system enclosure is a difficult challenge.

This problem is compounded by a further need to meet standard requirements on many consumer electronic devices. For example, rigorous standards on many aspects of device operation are imposed by organizations such as Underwriters Laboratories (UL). One such requirement relates to the temperature of external surfaces of the device, which must remain cool enough to prevent injury to users of the system. This means that heat may not be dispersed from a device through an external surface at a rate that would cause the temperature of the external surface to exceed maximum UL temperature requirements.

An additional design constraint is overall system cost. Materials that are able to effectively disperse heat while remaining cool are relatively expensive. A system and method that effectively disperses heat generated in an enclosure in a cost-effective manner while also facilitating compliance with external surface temperature requirements is desirable.

### SUMMARY OF THE INVENTION

Certain aspects commensurate in scope with the disclosed embodiments are set forth below. It should be understood that these aspects are presented merely to provide the reader with a brief summary of certain forms the invention might take and that these aspects are not intended to limit the scope of the invention. Indeed, the invention may encompass a variety of aspects that may not be set forth below.

The disclosed embodiments relate to a system and method that is adapted to cool a heat generating device. An electronic device in accordance with an exemplary embodiment of the present invention comprises an enclosure that contains a source of heat, and a cooling structure adjacent to the enclosure, the cooling structure being adapted to draw an internal intake comprising heat generated by the source of heat and to draw an external intake from outside the enclosure, the cooling structure being further adapted to combine the internal intake with the external intake to form an exhaust.

### BRIEF DESCRIPTION OF THE DRAWINGS

Advantages of the invention may become apparent upon reading the following detailed description and upon reference to the drawings in which:

FIG. 1 is a perspective view, including a blown up portion, of an electronic enclosure in accordance with an exemplary embodiment of the present invention;

FIG. 2 is a cutaway view of an electronic enclosure in accordance with an exemplary embodiment of the present invention; and

FIG. 3 is a flow chart of a method in accordance with exemplary an embodiment of the present invention.

### DETAILED DESCRIPTION

One or more specific embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

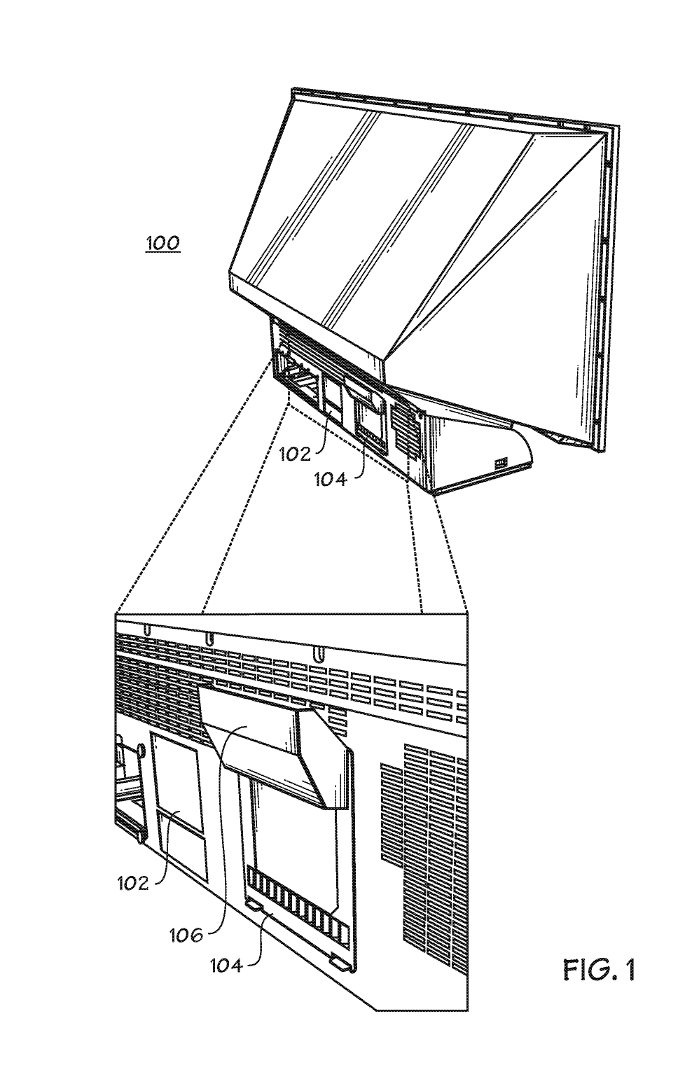

FIG. 1 is a perspective view, including a blown up portion, of an electronic enclosure in accordance with an exemplary embodiment of the present invention. The enclosure, which may comprise a projection television system, is generally referred to by the reference number 100. The enclosure 100 comprises a chassis cover 102. The chassis cover 102 allows access to the internal components contained in the enclosure 100.

A lamp access door 104 is also disposed on the back of the enclosure 100. The lamp access door 104 provides access to a lamp to facilitate periodic replacement thereof. A cooling structure 106 is disposed adjacent to the lamp access door 104. As explained below, the cooling structure 106 is adapted to remove heat from inside the enclosure 100 via a chimney effect while preventing access by a user to portions of the enclosure 100 that may be hot enough to cause injury.

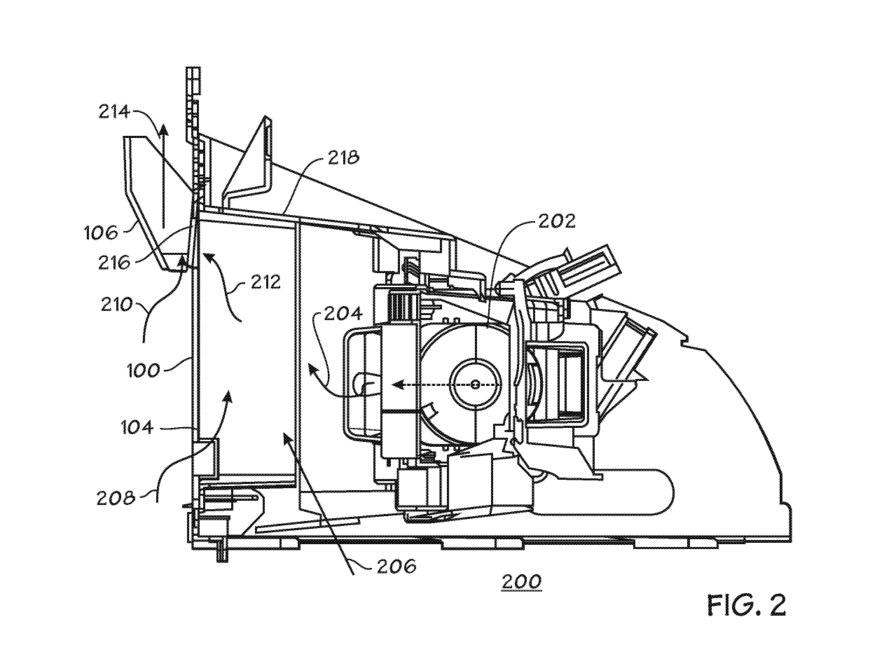

FIG. 2 is a cutaway view of the electronic enclosure 100 in accordance with an exemplary embodiment of the present invention. The cutaway diagram is generally referred to by the reference number 200. A lamp 202 is disposed inside the enclosure 100. The lamp 202 may comprise a high power bulb for use in generating an image that is displayed by a television system. The lamp 202 produces radiated heat, as indicated by the arrow 204.

The enclosure 100 is adapted to provide several airflows to remove the radiated heat 204, while maintaining the enclosure 100 at a temperature that will reduce the likelihood of injury to a user. One source of airflow may be a fan (not shown) disposed inside the enclosure 100.

The enclosure 100 may include louvers in its floor to facilitate entry of a floor intake, as indicated by an arrow 206. The floor intake 206 is adapted to travel through the interior of the enclosure 100 to facilitate dispersal of the radiated heat 204 through the back of the enclosure 100.

A second airflow may be pulled from outside the enclosure 100 through louvers in the lamp access door 104. This airflow is indicated by an arrow 208 in FIG. 2. Like the floor intake 206, the louver intake 208 assists with moving the radiated heat 204 out of the enclosure 100 via its back. A tunnel 218 may be disposed within the enclosure 100 to contain the radiated heat 204 and the various airflows within a relatively restricted portion of the enclosure 100.

In the exemplary embodiment illustrated in FIG. 2, the cooling structure 106 is disposed adjacent to the enclosure 100 and external thereto. The cooling structure 106 is adapted to receive an external chimney intake 210 from outside the enclosure 100. In addition, the cooling structure 106 is adapted to receive an internal chimney intake 212 from inside the enclosure 100. The cooling structure 106 may be formed integrally with the lamp access door 104 or the chassis of the enclosure 100. Alternatively, the cooling structure 106 may be a separate piece disposed adjacent to the enclosure 100.

In the exemplary embodiment illustrated in FIG. 2, the cooling structure is adapted to receive the internal chimney intake 212 through a plurality of louvers 216. The external chimney intake 210 mixes with the internal chimney intake 212 to create a Venturi flow within the cooling structure 106. This Venturi flow acts to effectively remove the radiated heat 204 from within the enclosure 100. The cooling structure 106 expels the mixture of the external chimney intake 210 and the internal chimney intake 212 via a chimney exhaust 214.

In the exemplary embodiment illustrated in FIG. 2, the cooling structure 106 is disposed such that it poses an obstacle to touching the louvers 216 by a user of the system. This feature makes it more difficult for a user to touch the louvers 216, which may be hot enough to cause injury. Thus, the cooling structure 106 helps to disperse the radiated heat 204 from within the enclosure 100, while reducing the chances of accidental injury to a user who may touch the enclosure 100. In addition, the cooling structure 106 may be positioned to reduce the undesirable escape via the louvers 216 of light rays emitted by the lamp 202 from within the enclosure 100.

Exemplary embodiments of the present invention further allow construction of the enclosure 100 with materials that have a relatively low heat resistance. For example, an exemplary embodiment of the present invention may allow the chassis cover 102 (FIG. 1) and/or the tunnel 218 to be constructed of a relatively low heat resistance material, which typically would cost less than a similar material having a higher heat resistance.

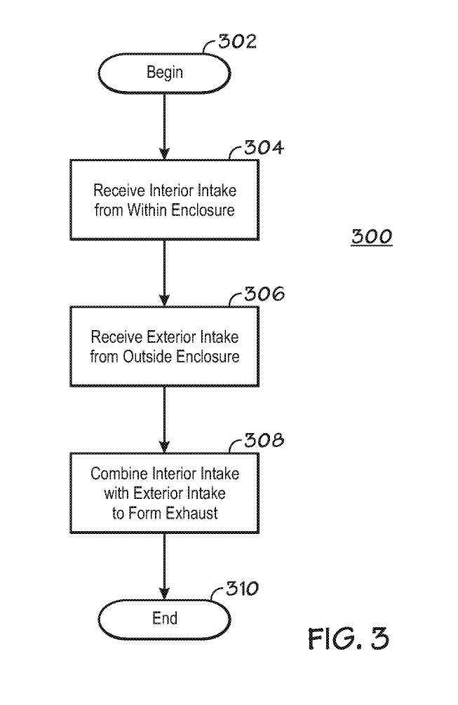

FIG. 3 is a flow chart of a method in accordance with exemplary an embodiment of the present invention. The process is generally referred to by the reference number 300. At block 302, the process begins. An interior intake, such as the interior intake 212 (FIG. 2) is received from within the enclosure 100 (FIG. 2) at block 304. As set forth above, the enclosure 100 (FIG. 2) may comprise a portion of an electronic device, such as a projection television. At block 306, an exterior intake, such as the exterior intake 210 (FIG. 2) is received from outside the enclosure 100 (FIG. 2). The interior intake 212 (FIG. 2) received at block 304 is combined with the exterior intake 210 (FIG. 2) received from outside the enclosure 100 (FIG. 2), as indicated at block 308. This combination forms an exhaust flow 214 (FIG. 2), which assists in dispersing heat from inside the enclosure 100 (FIG. 2). As set forth above, the combination of the interior intake 212 (FIG. 2) with the exterior intake 210 (FIG. 2) in a cooling structure such as the cooling structure 106 (FIG. 2) may form a Venturi flow, which assists in the removal of radiated heat 204 (FIG. 2) from within the enclosure 100 (FIG. 2). At block 310, the process end.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. An electronic device, comprising:
an enclosure that contains a source of heat; and
a cooling structure adjacent to the enclosure, the cooling structure being adapted to draw an internal intake comprising heat generated by the source of heat and to draw an external intake from outside the enclosure, the cooling structure being further adapted to combine the internal intake with the external intake to form an exhaust.

2. The electronic device recited in claim 1, wherein the enclosure is adapted to draw a second external intake that combines with the heat generated by the source of heat to form the internal intake.

3. The electronic device recited in claim 2, wherein the enclosure is adapted to draw a third external intake that combines with the heat generated by the source of heat and the second external intake to form the internal intake.

4. The electronic device recited in claim 1, wherein the electronic device comprises a projection television system.

5. The electronic device recited in claim 1, wherein the source of heat comprises a lamp.

6. The electronic device recited in claim 1, wherein the exhaust comprises a Venturi flow.

7. The electronic device recited in claim 1, wherein the cooling structure is formed as an integral portion of the enclosure.

8. The electronic device recited in claim 1, wherein the interior intake exits the enclosure through at least one louver.

9. The electronic device recited in claim 1, wherein the interior intake exits the enclosure through an opening to which access from outside the enclosure is at least partially blocked by the cooling structure.

10. A method of cooling an enclosure, comprising the acts of:
receiving an interior intake comprising heat from a source of heat disposed in an enclosure;
receiving an exterior intake from outside the enclosure; and
combining the internal intake with the external intake to form an exhaust.

11. The method recited in claim 10, comprising:
receiving a second external intake inside the enclosure; and
combining the second external intake with the heat generated by the source of heat to form the internal intake.

12. The method recited in claim 11, comprising:
receiving a third external intake inside the enclosure; and
combining the third external intake with the heat generated by the source of heat and the second external intake to form the internal intake.

13. The method recited in claim 10, wherein the enclosure comprises a projection television system.

14. The method recited in claim 10, wherein the source of heat comprises a lamp.

15. The method recited in claim 10, wherein the act of combining the internal intake with the external intake to form an exhaust comprises producing a Venturi flow.

16. An electronic device, comprising:
an enclosure that contains a source of heat; and
means for cooling the enclosure by drawing an internal intake comprising heat from inside the enclosure and an external intake from outside the enclosure, and combining the internal intake with the external intake to form an exhaust.

17. The electronic device recited in claim 16, comprising means for drawing a second external intake that is combined with the heat to form the internal intake.

18. The electronic device recited in claim 17, comprising means for drawing a third external intake that is combined with the heat and the second external intake to form the internal intake.

19. The electronic device recited in claim 16, wherein the electronic device comprises a projection television system.

20. The electronic device recited in claim 16, wherein the interior intake exits the enclosure through an opening to which access from outside the enclosure is at least partially blocked by the means for cooling.
